(19) United States
(12) Patent Application Publication
(10) Pub. No.: US 2021/0337688 A1
(43) Pub. Date: Oct. 28, 2021

(54) BENDABLE COVER PLATE AND FLEXIBLE DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xiaoming GE, Wuhan, Hubei (CN)

(21) Appl. No.: 16/605,038

(22) PCT Filed: Feb. 20, 2019
(86) PCT No.: PCT/CN2019/075527

§ 371 Date: Oct. 14, 2019

(30) Foreign Application Priority Data
Dec. 20, 2018 (CN) 201811565611.5

(51) Int. Cl. H05K 5/03; H01L 27/32; H01L 51/00; H01L 51/52

(52) U.S. Cl. CPC H05K 5/03; H01L 27/3244; C03C 21/002; H01L 51/524; H01L 2251/5338; H01L 51/0097

(57) ABSTRACT

A bendable cover plate and a flexible display device are provided. The bendable cover plate makes a bending region have an arch bridge structure by providing a groove in a corresponding bending region, thereby effectively enhancing bending ability. Adopting a glass material which has undergone doping treatment and laser treatment changes original structure and properties of the glass material, thereby greatly improving a surface hardness, correspondingly improving bending ability and surface hardness of the flexible display device, and improving the bending ability of the flexible display device while satisfying a customer's touch demand.

### FIELD OF INVENTION

The present disclosure relates to the field of flexible display technologies, and more particularly to a bendable cover plate and a flexible display device.

### BACKGROUND OF INVENTION

Organic light emitting diode (OLED) displays have many advantages such as self-luminous properties, low driving voltage, high luminous performance, short response times, high definition, high contrast ratio, near 180° viewing angles, wide temperature ranges, flexible display performance, and large-area full-color display performance. The OLED displays are recognized by the industry as the most promising display device. At present, OLED technologies are more and more widely used in mobile phones, digital video cameras, notebook computers, televisions, and other products. Flexible OLED technologies have attracted extensive attention, and advantages thereof are that bendable OLED display devices can be realized. Consumers are concerned about whether these new mobile devices are well designed, lightweight, thin, and compact. Mobile brand manufacturers want panel manufacturers to offer foldable display panels with small bend radii (less than 1-3 mm), therefore, the mobile brand manufacturers can make slim and compact foldable devices.

Separate flexible OLED panel can be easily folded, a flexible OLED module, which typically includes a panel, a polarizer, a touch sensor, and a cover glass stacked with each other, is not easily folded because flexibility thereof is not enough and each structural layer thereof is subjected to different bending and folding stresses or tensile forces. In order to implement foldable OLED display panels, panel manufacturers need to create a more compact and slimmer module structure. It is often considered to reduce a thickness of the module by changing conventional structures of the polarizer, the touch sensor, and the cover glass. However, changing the conventional structure such as a thickness of the cover glass may reduce a hardness of a screen, making a consumer's experience bad. Therefore, there is a need to develop a structure of a flexible foldable display device that can improve a surface hardness to meet needs of consumers and mobile brand manufacturers and meet surface hardness requirements while improving the bending ability of the flexible display device.

### SUMMARY OF INVENTION

An object of the present disclosure is to provide a bendable cover plate in which bending ability and surface hardness are enhanced, thereby improving a bending ability of a flexible display device while satisfying a surface hardness requirement.

Another object of the present invention is to provide a flexible display device which adopts the above-mentioned bendable cover plate to meet the surface hardness requirement while improving the bending ability.

To achieve the above object, an embodiment of the present disclosure provides a bendable cover plate. The bendable cover plate includes at least two non-bending regions and a bending region connecting adjacent two non-bending regions. A surface of a side of the bending region is provided with a groove, and the bending region is gradually reduced in thickness from two sides of each of the at least two non-bending regions toward a center of the bending region by the groove to form an arch bridge structure. The bendable cover plate is a doped and laser treated glass plate.

In an embodiment of the present disclosure, a doping treatment to the doped and laser treated glass plate refers to a potassium ion doping process.

In an embodiment of the present disclosure, a laser treatment to the doped and laser treated glass plate refers to a laser treatment using a laser having a wavelength of 308 nm at a temperature of 700° C. or higher.

In an embodiment of the present disclosure, a thickness of each of the at least two non-bending regions ranges between 60 microns and 80 microns.

In an embodiment of the present disclosure, a depth of the groove ranges between 40 microns and 60 microns.

In an embodiment of the present disclosure, a depth of the groove is ⅔ of a thickness of each of the at least two non-bending regions.

In an embodiment of the present disclosure, a width of groove ranges between 12 mm and 20 mm.

An embodiment of the present disclosure further provides a flexible display device. The flexible display device includes a flexible display panel and the above bendable cover plate disposed on the flexible display panel. The groove is disposed on a surface of a side of the bendable cover plate adjacent to the flexible display panel.

In an embodiment of the present disclosure, the flexible display device further includes a middle frame configured to support the flexible display panel and disposed on a side of the flexible display panel away from the bendable cover plate.

In an embodiment of the present disclosure, the flexible display panel is an organic light emitting diode (OLED) display panel.

Beneficial effects of the embodiment of present disclosure are that, the bendable cover plate of the embodiment of present disclosure can make the bending region have an arch bridge structure by providing the groove in the corresponding bending region, thereby effectively enhancing bending ability, and adopting the glass material which has undergone doping treatment and laser treatment can change an original structure and properties of the glass material, thereby greatly improving surface hardness, correspondingly improving bending ability and surface hardness of the flexible display device, breaking a contradiction of a current flexible display device, “hard cannot be folded, folding cannot be hard”, and improving the bending ability of the flexible display device while satisfying a customer's touch demand. The flexible display device adopts the above-mentioned bendable cover plate to meet the surface hardness requirement while improving the bending ability.

In order to further understand the features and technical contents of the present invention, refer to the following detailed description and drawings related to the present disclosure. The drawings are provided for reference and description only and are not intended to limit the present disclosure.

### DESCRIPTION OF DRAWINGS

The technical solutions and other advantageous effects of the present disclosure will be apparent from the following detailed description of embodiments of the present disclosure.

FIG. 1 is a schematic structural diagram of a flexible display device according to an embodiment of the present disclosure.

### DETAILED DESCRIPTION OF PREFERRED EMBODIMENTS

In order to further illustrate the technical means and effects of the present disclosure, the following detailed description will be made in conjunction with the preferred embodiments of the present disclosure and the accompanying drawings.

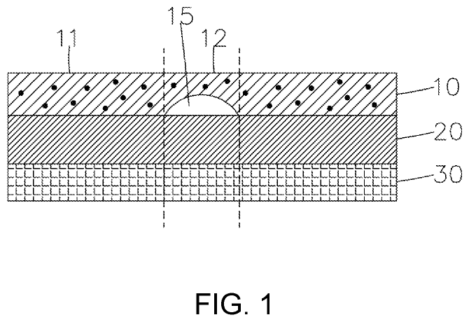

Referring to FIG. 1, an embodiment of the present disclosure provides a bendable cover plate 10 including at least two non-bending regions 11 and a bending region 12 connecting adjacent two non-bending regions 11.

In details, a surface of a side of the bending region 12 is provided with a groove 15 through which a thickness of the bending region 12 is gradually reduced from two sides of each of the at least two non-bending regions 11 a center of the bending region to form an arch bridge structure. Therefore, bending ability of the bending region 12 can be effectively enhanced.

In details, the bendable cover plate 10 is a doped and laser treated glass plate, thereby changing an original material structure and properties of the glass plate, thereby improving surface hardness thereof.

In details, ordinary glass is relatively fragile, hardness thereof is insufficient, and the ordinary glass contains a large amount of sodium ions (Na+). An embodiment of the present disclosure performs potassium ion (K+) doping on the glass plate of the bendable cover plate 10. In details, doping materials contain potassium ions such as potassium hydroxide (KOH). The potassium ions with larger ionic radius are substituted for the sodium ions in the original glass material, which increases the hardness of material and improves flexibility, this facilitates the bending of the bendable cover plate 10.

In details, an embodiment of the present disclosure performs laser treatment to the glass plate of the bendable cover plate 10, such that the material structure of the glass plate is changed from the inside to improve toughness of the material, thereby facilitating the bending of the bendable cover plate 10. In details, the glass plate of the bendable cover plate 10 is subjected to laser treatment using a laser having a wavelength of 308 nm at a temperature of 700° C. or higher.

In details, a thickness of each of the at least two non-bending regions 11 of the bendable cover plate 10 ranges between 60 microns and 80 microns.

In details, a depth of the groove 15 ranges between 40 microns and 60 microns.

Preferably, in order to improve stability of the arch bridge structure, referring to famous Chinese arch bridge construction, “bao belt bridge”, an arch depth of the arch bridge structure of the bending region 12, that is, a depth of the groove 15 is ⅔ of a thickness of each of the at least two non-bending regions 11 of the bendable cover plate 10.

In details, an arch length of the arch structure of the bending region 12, that is, a width of groove 15 ranges between 12 mm and 20 mm.

In details, the groove 15 of the bending zone 12 is formed by cutting or grinding.

The bendable cover plate 10 of the embodiment of present disclosure can make the bending region 12 have an arch bridge structure by providing the groove 15 in the corresponding bending region 12, thereby effectively enhancing bending ability, and adopting the glass material which has undergone doping treatment and laser treatment can change an original structure and properties of the glass material, thereby greatly improving surface hardness, correspondingly improving bending ability and surface hardness of the flexible display device, breaking a contradiction of a current flexible display device, “hard cannot be folded, folding cannot be hard”, and improving the bending ability of the flexible display device while satisfying a customer's touch demand.

As illustrated in FIG. 1, an embodiment of the present disclosure further provides a flexible display device based on the above bendable cover plate 10. The flexible display device includes a flexible display panel 20, the above bendable cover plate 10 disposed on the flexible display panel 20, and a middle frame 30 configured to support the flexible display panel 20 and disposed on a side of the flexible display panel 20 away from the bendable cover plate 10. The specific technical features of the bendable cover plate 10 are the same as those of the foregoing embodiment, and details are not described herein again.

In details, the groove 15 is disposed on a surface of a side of the bendable cover plate 10 adjacent to the flexible display panel 20.

In details, the flexible display panel 20 is an organic light emitting diode (OLED) display panel. In details, the flexible display panel 20 includes a flexible substrate, a thin film transistor (TFT) layer disposed on the flexible substrate, an OLED device layer disposed on the TFT layer, and a thin film encapsulation layer (not shown) disposed on the flexible substrate, the TFT layer, and the OLED device layer and completely covering the OLED device layer.

In details, the flexible display device further includes a touch function layer and a polarizer (not shown) disposed between the flexible display panel 20 and the bendable cover plate 10. The flexible display device of the embodiment of the present disclosure adopts the above-mentioned bendable cover plate 10. The bendable cover plate 10 of the embodiment of present disclosure can make the bending region 12 have an arch bridge structure by providing the groove 15 in the corresponding bending region 12, thereby effectively enhancing bending ability, and adopting the glass material which has undergone doping treatment and laser treatment can change an original structure and properties of the glass material, thereby greatly improving surface hardness, correspondingly improving bending ability and surface hardness of the flexible display device, breaking a contradiction of a current flexible display device, “hard cannot be folded, folding cannot be hard”, and improving the bending ability of the flexible display device while satisfying a customer's touch demand.

In summary, the bendable cover plate of the embodiment of present disclosure can make the bending region have an arch bridge structure by providing the groove in the corresponding bending region, thereby effectively enhancing bending ability, and adopting the glass material which has undergone doping treatment and laser treatment can change an original structure and properties of the glass material, thereby greatly improving surface hardness, correspondingly improving bending ability and surface hardness of the flexible display device, breaking a contradiction of a current flexible display device, “hard cannot be folded, folding cannot be hard”, and improving the bending ability of the flexible display device while satisfying a customer's touch demand. The flexible display device adopts the above-mentioned bendable cover plate to meet the surface hardness requirement while improving the bending ability.

In the above, various other corresponding changes and modifications can be made by those skilled in the art according to the technical solutions and technical concept of the present disclosure, and all such changes and modifications are within the scope of the claims of the present disclosure.

What is claimed is:

1. A bendable cover plate, comprising:
at least two non-bending regions; and
a bending region connecting adjacent two non-bending regions;
wherein a surface of a side of the bending region is provided with a groove, and the bending region is gradually reduced in thickness from two sides of each of the at least two non-bending regions toward a center of the bending region by the groove to form an arch bridge structure; and
wherein the bendable cover plate is a doped and laser treated glass plate.

2. The bendable cover plate according to claim 1, wherein a doping treatment to the doped and laser treated glass plate refers to a potassium ion doping process.

3. The bendable cover plate according to claim 1, wherein a laser treatment to the doped and laser treated glass plate refers to a laser treatment using a laser having a wavelength of 308 nm at a temperature of 700° C. or higher.

4. The bendable cover plate according to claim 1, wherein a thickness of each of the at least two non-bending regions ranges between 60 microns and 80 microns.

5. The bendable cover plate according to claim 1, wherein a depth of the groove ranges between 40 microns and 60 microns.

6. The bendable cover plate according to claim 1, wherein a depth of the groove is ⅔ of a thickness of each of the at least two non-bending regions.

7. The bendable cover plate according to claim 1, wherein a width of groove ranges between 12 mm and 20 mm.

8. A flexible display device, comprising:
a flexible display panel; and
the bendable cover plate according to claim 1 disposed on the flexible display panel;
wherein the groove is disposed on a surface of a side of the bendable cover plate adjacent to the flexible display panel.

9. The flexible display device according to claim 8, further comprising a middle frame configured to support the flexible display panel and disposed on a side of the flexible display panel away from the bendable cover plate.

10. The flexible display device according to claim 8, wherein the flexible display panel is an organic light emitting diode (OLED) display panel.
